(19) United States
(12) Patent Application Publication
(10) Pub. No.: US 2024/0321570 A1
(43) Pub. Date: Sep. 26, 2024

(54) ETCHING METHOD AND MANUFACTURING METHOD OF A SEMICONDUCTOR MEMORY DEVICE

(71) Applicant: Kioxia Corporation, Tokyo (JP)

(72) Inventors: Ayata HARAYAMA, Nagoya Aichi (JP); Tsubasa IMAMURA, Kuwana Mie (JP)

(21) Appl. No.: 18/433,787

(22) Filed: Feb. 6, 2024

(30) Foreign Application Priority Data
Mar. 20, 2023 (JP) 2023-044121

(51) Int. Cl. H01L 21/02; H01L 21/311

(52) U.S. Cl. CPC H01L 21/02211; H01L 21/31116

(57) ABSTRACT

According to one embodiment, an etching method includes forming a first film on the inner wall surface of the recess by supplying a precursor including silicon to the recess. The etching method includes oxidizing an upper region of the first film on the inner wall surface by an oxidation process, thereby forming an oxidized portion in the upper region. The etching method includes silylating the oxidized portion by supplying a silylating agent to the recess and etching the recess after supplying the silylating agent to increase the depth of the recess.

### CROSS-REFERENCE TO RELATED APPLICATION

This application is based upon and claims the benefit of priority from Japanese Patent Application No. 2023-044121, filed Mar. 20, 2023, the entire contents of which are incorporated herein by reference.

### FIELD

Embodiments described herein relate generally to an etching method and a manufacturing method of semiconductor memory devices.

### BACKGROUND

In a manufacturing method for semiconductor devices, such as three-dimensional memory, a technique for forming a recess with a high aspect ratio in an object to be processed by etching is known.

### BRIEF DESCRIPTION OF THE DRAWINGS

FIG. 1 is a flowchart of an etching method and a semiconductor device manufacturing method according to embodiments.

FIG. 2 is a schematic diagram of semiconductor manufacturing apparatuses that can be used in the etching method and the semiconductor device manufacturing method according to the embodiments.

FIG. 3 is a cross-sectional schematic diagram of the structure of an object to be processed according to the embodiments.

FIG. 4 is a cross-sectional schematic diagram illustrating a precursor supply process according to the embodiments.

FIG. 5 is a schematic diagram for explaining the formation of a precursor film according to the embodiments.

FIG. 6 is a cross-sectional schematic diagram illustrating an oxidation process according to the embodiments.

FIG. 7 is a schematic diagram illustrating an oxidation of the precursor film according to the embodiments.

FIG. 8 is a cross-sectional schematic diagram illustrating a silylation process according to the embodiments.

FIG. 9 is a schematic diagram illustrating a formation of a silylated portion according to the embodiments.

FIG. 10 is a cross-sectional schematic diagram illustrating an etching process according to the embodiments.

FIG. 11 is a cross-sectional schematic diagram illustrating a memory layer formation process according to the embodiments.

### DETAILED DESCRIPTION

The embodiments provide an etching method and a manufacturing method of a semiconductor memory device in which a memory hole with a wide bottom diameter can be formed under conditions of a high processing accuracy.

In general, according to the embodiments, an etching method includes forming a first film on the inner wall surface of the recess by supplying a precursor including silicon to the recess. The etching method includes oxidizing an upper region of the first film on the inner wall surface by an oxidation process, thereby forming an oxidized portion in the upper region. The etching method includes silylating the oxidized portion by supplying a silylating agent to the recess and etching the recess after supplying the silylating agent to increase the depth of the recess.

The following is a description of the embodiments with reference to the drawings. The relationships between the thickness and planar dimensions of each component illustrated in the drawings and the ratio between the thicknesses of the components may differ from an actual product. In addition, in the drawings, the same numbers are attached to substantially identical components and explanations are omitted as appropriate.

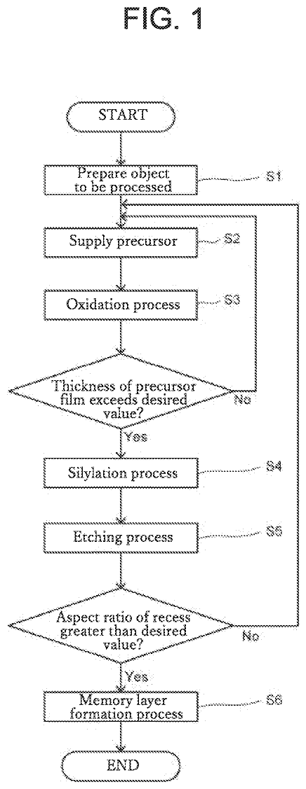

FIG. 1 shows an example of the etching method of the embodiments.

FIG. 1 is a flowchart for explaining an example of an etching method of the embodiments and an example of a manufacturing method of a semiconductor device. The semiconductor device is, for example, a three-dimensional memory device. The semiconductor device manufacturing method comprises a preparation process S1, a precursor supply process S2, an oxidation process S3, a silylation process S4, an etching process S5, and a memory layer formation process S6. These processes may be performed using different apparatuses, or they may be performed using the same apparatus so that the object to be processed is not exposed to the atmosphere outside the apparatus.

### Semiconductor Manufacturing Apparatus

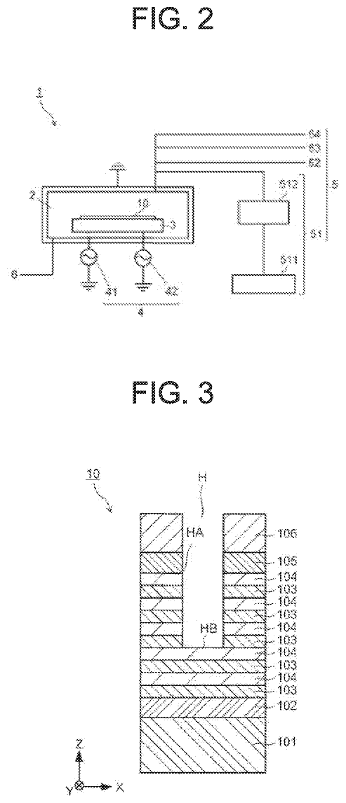

FIG. 2 is a schematic diagram showing an example of a semiconductor manufacturing apparatus as a processing apparatus that can be used for the etching method and semiconductor device manufacturing method of the embodiments. FIG. 2 shows an example of semiconductor manufacturing apparatus (e.g., etching apparatus) capable of continuously performing the precursor supply process S2, the oxidation process S3, the silylation process S4, and the etching process S5.

A semiconductor manufacturing apparatus 1 shown in FIG. 2 comprises a chamber 2, a holder 3, a power supply unit 4, a gas supply unit 5, and a gas discharge unit 6.

The chamber 2 is a space in which an object to be processed 10 can be etched by sputtering using plasma (plasma etching).

A holder 3 is provided in the chamber 2. The holder 3 functions as a platform on which the object to be processed 10 is placed. The holder 3 includes, for example, an electrostatic chuck. The holder 3 may be connected to a temperature regulator.

The power supply unit 4 includes a high-frequency power supply 41 and a high-frequency power supply 42.

The high-frequency power supply 41 is connected to the chamber 2.

The high-frequency power supply 41 has the function of supplying high-frequency power to the chamber 2. This allows plasma to be generated in the chamber 2. The high-frequency power is, for example, between 50 W and 5,000 W. The frequency of the high-frequency power is, for example, between 20 MHz and 200 MHZ.

The high-frequency power supply 42 has the function of supplying high-frequency power to the holder 3. This allows the energy of the ions striking the object to be processed 10 to be controlled. The high-frequency power is, for example, between 100 W and 1,000 W. The frequency of the high-frequency power is, for example, from 0.1 MHz to 13.56 MHz.

The gas supply unit 5 includes, for example, a gas supply source 51 that supplies a first gas, a gas supply source 52 that supplies a second gas, a gas supply source 53 that supplies a third gas, and a gas supply source 54 that supplies a fourth gas. Each of the gas supply sources 51 through 54 is connected to the chamber 2. The gas supply unit 5 may further comprise mass flow controllers. The flow rate of each of the first through fourth gases may be controlled by a respective mass flow controller.

Gas discharge unit 6 is connected to chamber 2. The gas discharge unit 6 has the function of depressurizing the interior of the chamber 2 to create a vacuum, and discharging the gases from the chamber 2. The gas discharge unit 6 includes, for example, a valve and a vacuum pump connected to the chamber 2.

The power supply unit 4, gas supply unit 5, and gas discharge unit 6 may be controlled by a control circuit. The control circuit includes hardware, for example, a processor. Each operation may be stored as an operation program in a computer-readable recording medium such as a memory, and the hardware may execute each operation by reading the operation program stored in the recording medium.

### Preparation Process S1

In the example of preparation process S1, the object to be processed 10 to be etched by etching process S5 is prepared. The object to be processed 10 is placed on the holder 3 using a transfer arm and held in a vacuum.

FIG. 3 is a cross-sectional schematic diagram showing an example of the structure of the object to be processed 10. FIG. 3 shows a portion of an X-Z cross section of the object to be processed 10. FIG. 3 shows the X axis, the Y axis orthogonal to the X axis, and the Z axis orthogonal to the X and Y axes.

The object to be processed 10 has a substrate 101, a lower layer 102, a plurality of first layers 103, a plurality of second layers 104, an upper layer 105, a mask layer 106, and a recess H. The object to be processed 10 is not limited to the structure shown in FIG. 3.

Examples of substrate 101 are a semiconductor substrate (wafer) such as silicon substrate or silicon carbide substrate, an insulating substrate such as glass, quartz, or sapphire substrates, or a compound semiconductor substrate such as GaAs substrate. The surface of the substrate 101 extends along, for example, the x-axis and y-axis. The thickness direction of the substrate 101 is, for example, along the Z-axis.

The lower layer 102 is provided on the substrate 101. The lower layer 102 can be an insulating layer, such as a silicon oxide layer or a silicon nitride layer, or a conductive layer provided between insulating layers. The lower layer 102 is not necessarily provided.

The first layers 103 and the second layers 104 are alternately stacked on the lower layer 102 to form a stacked film. If the lower layer 102 is not provided, one of the first layers 103 or the second layers 104 is formed directly on the substrate 101. The number of layers of the first layers 103 and the second layers 104 is not limited to the number shown in FIG. 3.

The first layers 103 are sacrificial layers. The sacrificial layers will be replaced by conductive layers later. The first layers 103 include, for example, a silicon nitride layer.

The second layers 104 include, for example, a silicon oxide layer.

The upper layer 105 is provided on the top of the stacking film of the first layers 103 and the second layers 104. The upper layer 105 can be an insulating layer, such as a silicon oxide layer or a silicon nitride layer, or a conductive layer between insulating layers. The upper layer 105 is not necessarily provided.

The mask layer 106 is provided on the top of the upper layer 105. The mask layer 106 functions as a mask for etching a portion of the upper layer 105. Examples of the mask layer 106 include an organic hard mask and the like. The mask layer 106 may be removed after etching a portion of the upper layer 105.

The recess H penetrates the upper layer 105 to expose a portion of the stacked film of the first layers 103 and the second layers 104. The recess H has an inner wall surface HA and an inner bottom surface HB. The inner wall surface HA extends in a direction intersecting the stacking direction of the first layers 103 and the second layers 104. The inner bottom surface HB extends in a direction intersecting the inner wall surface HA. The recess H is, for example, a hole shape in the x-y plane. The shape of the recess H is not limited to the hole shape. The recess H can be formed in the stacked film of the first layers 103 and the second layers 104 by reactive ion etching (RIE), for example.

### Precursor Supply Process S2

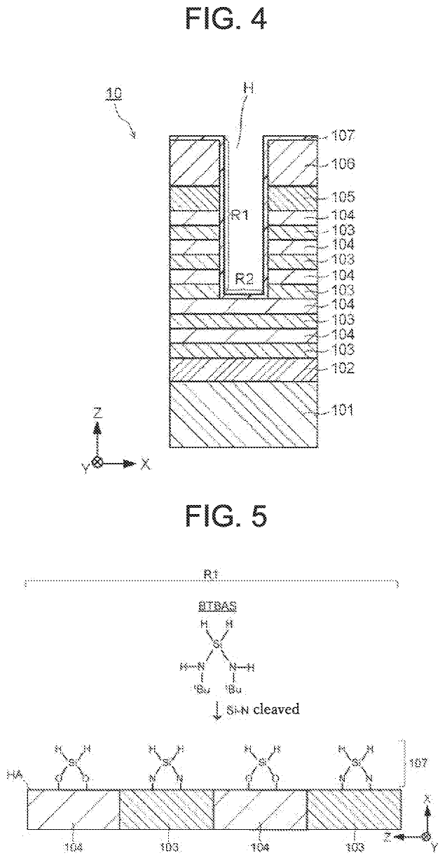

FIG. 4 is a cross-sectional schematic diagram illustrating an example of the precursor supply process S2. FIG. 4 shows a portion of the X-Z cross section of the object to be processed 10.

In the example of precursor supply process S2, a precursor layer 107, also referred to herein as a “precursor film”, is formed by supplying an oxide precursor to the recess H. The precursor includes silicon. The precursor film 107 covers each of the inner wall surface HA and the inner bottom surface HB of the recess H. The precursor film 107 has a region R1 facing the inner wall surface HA and a region R2 facing the inner bottom surface HB. The precursor film 107 need not be formed on the inner bottom surface HB of the recess H.

In the example of the precursor supply process S2, for example, a first gas is supplied to the chamber 2 from the gas supply source 51 without supplying high frequency power from the power supply unit 4 shown in FIG. 2.

The first gas contains a precursor of an oxide having silicon. It is necessary that the precursor have Si—H bonds, and it is allowable but not necessary that the precursor have Si—O bonds. The precursor may also have Si—N bonds. The precursor may be, for example, at least one of dichlorosilane (DCS), tetrachlorosilane (SiCl₄), bis(t-butylamino) silane (BTBAS), bis(diethylamino)silane (BDEAS), etc.

When the precursor is vaporized from precursor liquid, the gas supply source 51 uses a liquid feeder 511 that supplies the precursor liquid and a vaporizer 512 that vaporizes the precursor liquid, as shown in FIG. 2. When the precursor is instead provided in a gas state, the gas supply source 51 supplies the precursor to the chamber 2 without the liquid feeder 511 and the vaporizer 512.

The precursor is adsorbed on the surfaces of the inner wall surface HA and the inner bottom surface HB to form a precursor film 107. After the formation of the precursor film 107, the first gas in chamber 2 is discharged through gas discharge unit 6.

FIG. 5 is a schematic diagram to illustrate an example of forming the precursor film 107. FIG. 5 shows a portion of the X-Z cross section. FIG. 5 shows an example of the formation of the precursor film 107 on the first layers 103 and the second layers 104 on the inner wall surface HA. When the precursor is BTBAS, the Si—N bonds of the BTBAS molecules are cleaved and the cleaved portions of the silicon atoms bond with the nitrogen atoms on the surface of the first layers 103 of the inner wall surface HA to form a —N—Si—H bonds, while the cleaved portions of the silicon atoms bond with the oxygen atoms on the surface of the second layers 104 of the inner wall surface HA to form an —O—Si—H bonds. Thus, the precursor film 107 has silicon atoms, hydrogen atoms, oxygen atoms, and nitrogen atoms as shown in FIG. 5. Other parts of the surface of the recess H, such as the surface of the inner bottom surface HB, may also undergo the same reaction as the inner wall surface HA. Thus, the precursor film 107 can be formed. The number of the —O—Si—H and the —N—Si—H bonds is not limited to the number shown in FIG. 5.

### Oxidation Process S3

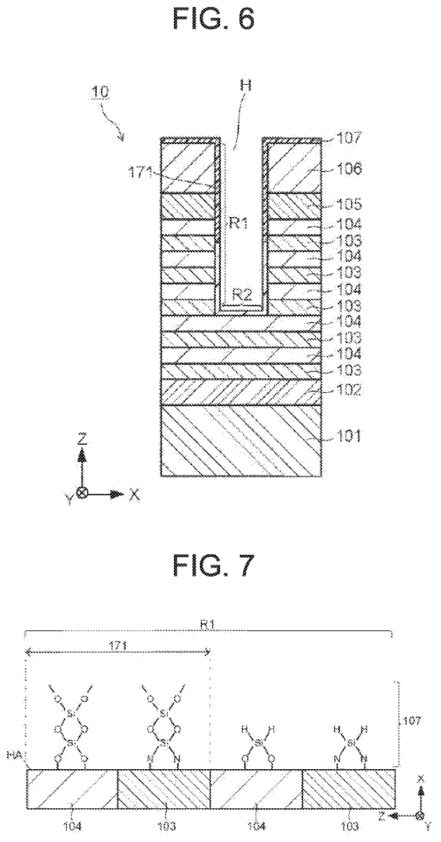

FIG. 6 is a cross-sectional schematic diagram to illustrate an example of the oxidation process S3. FIG. 6 shows a portion of the X-Z cross section of the object to be processed 10.

In the example of oxidation process S3, a part of the region R1 is oxidized in the Z direction from the top of the region R1 toward the bottom of the region R1 to form an oxidized portion 171 by an oxidation process. The oxidation process is, for example, an oxygen plasma treatment. The oxygen plasma treatment can be performed, for example, by supplying a second gas containing oxygen to the chamber 2 from gas supply source 52 shown in FIG. 2, and supplying high-frequency power from power supply unit 4 to generate oxygen plasma in the chamber 2. The supply of the second gas and the high-frequency power is stopped after the oxidation process.

FIG. 7 is a schematic diagram illustrating an example of oxidation of the precursor film 107. FIG. 7 shows a portion of the X-Z cross section. FIG. 7 shows an example of oxidation of the first layers 103 and the second layers 104 in the part of the region R1 formed on the inner wall surface HA. The Si—H bonds on the surface of the precursor film 107 are cleaved by oxygen plasma treatment, and the cleaved portions of the silicon atoms bond with the oxygen atoms in the second gas to form-O—Si bonds. This can form an oxidized portion 171 that includes oxides. On the other hand, the lower region of the region R1 below the oxidized portion 171 in the Z direction and the region R2 are non-oxidized portions that are not oxidized by the oxidation treatment such that the precursor film 107 with the —O—Si—H bonds and the —N—Si—H bonds still remain on the lower region of the region R1 below the oxidized portion 171 and the region R2. The —O—Si bonds are formed in the respective surface portions of some of first layers 103 and second layers 104 in the precursor film 107. The number of the —O—Si bonds is not limited to the number shown in FIG. 7.

The length of the oxidized portion 171 in the depth direction of the recess H is, for example, 80% or more of the depth of the recess H relative to the length before the oxidation process. This prevents the inner wall HA from being unnecessarily etched by the etching process S5 to increase the diameter or other width of the recess H. The length of the oxidized portion 171 can be adjusted, for example, by changing the treatment time of the oxygen plasma treatment. After the oxidation treatment, the gas in the chamber 2 is discharged through the gas discharge unit 6.

The precursor supply process S2 and the oxidation process S3 may be repeated until the thickness of the precursor film 107 exceeds a desired value.

### Silylation Process S4

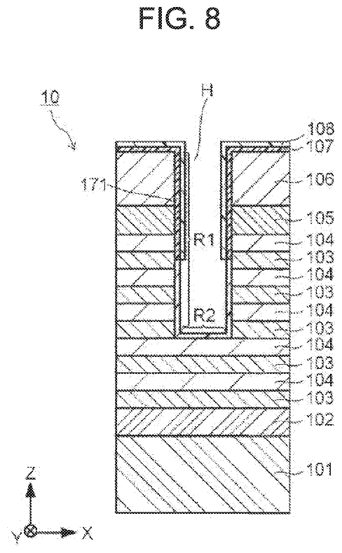

FIG. 8 is a cross-sectional schematic diagram illustrating an example of the silylation process S4. FIG. 8 shows a portion of the X-Z cross section of the object to be processed 10.

In the example of silylation process S4, a silylating agent is supplied to the recess H to silylate the oxidized portion 171 to form a silylated portion 108 on the oxidized portion 171. The silylating agent is supplied to the chamber 2 by supplying a third gas containing the silylating agent from the gas supply source 53 to the chamber 2 without supplying high frequency power from the power supply unit 4 shown in FIG. 2. The supply of the third gas is stopped after the silylation process. When the third gas is generated by vaporizing a silylating agent liquid, a liquid feeder and vaporizer may be provided in the gas supply source 53 as in the gas supply source 51.

The silylating agent is, for example, a silane compound containing a silicon atom, a hydrogen atom, and a carbon atom. The silylating agent may have Si—N bonds. The silylating agent may be, for example, at least one of an aminosilane compound, a chlorosilane compound, a methoxysilane compound, and cyclic silane compound.

The aminosilane compound may be, for example, at least one of N-(trimethylsilyl)dimethylamine (TMSDMA), hexamethyldisilazane (HMDS), and n-octyldimethyl (dimethylamino)silane (ODMDMAS). The silylating agent may also include alkanes represented by CₙH₂ₙ₊₂ (n is a natural number greater than or equal to 2).

Examples of the chlorosilane compound include octadecyltrichlorosilane (ODTC). Examples of the methoxirane compound include octadecyltrimethoxysilane (ODMS). Examples of the cyclic silane compound include N-methyl-aza-2,2,4-methylsilacyclopentane (CAZ).

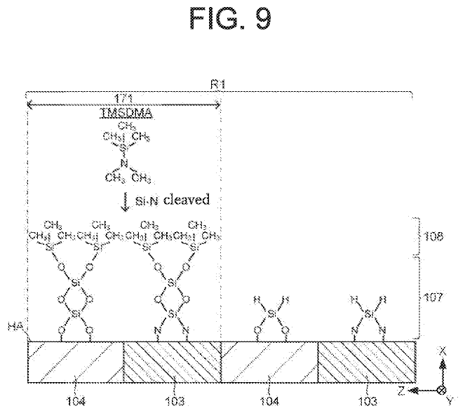

FIG. 9 is a schematic diagram illustrating an example of the formation of the silylated portion 108. FIG. 9 shows a portion of an X-Z cross section. For example, when the silylating agent is TMSDMA, the silylation reaction cleaves the Si—N bonds in the molecules of TMSDMA, and the cleaved portions of the silicon atoms bond with the oxygen atoms on the oxidized portion 171 to form Si—O—Si—(CH₃)₃ bonds. Thus, the silylated portion 108 has silicon atoms, oxygen atoms, carbon atoms, and hydrogen atoms. The Si—O—Si—(CH₃)₃ bonds are formed at upper surface portions of the oxidized portion 171. The number of Si—O—Si—(CH₃)₃ bonds is not limited to the number shown in FIG. 9.

On the other hand, the lower region below the oxidized portion 171 and region R2 remain with the —O—Si—H bonds because they are non-oxidized portions that have not been oxidized by the oxidation process. Therefore, they have hydrogen atoms at the ends. In these portions, the silylation reaction does not occur. Therefore, the silylated portion 108 is not formed over the lower region below the oxidized portion 171 and the region R2. After the silylation process S4, the gas in chamber 2 is discharged through gas discharge unit 6.

### Etching Process S5

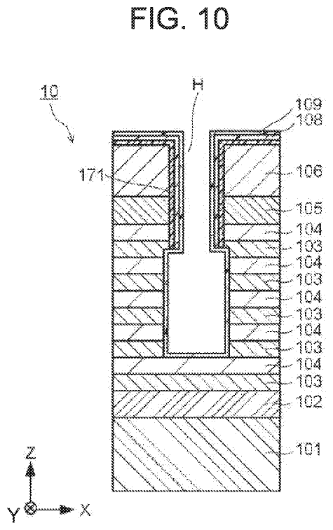

FIG. 10 is a cross-sectional schematic diagram to illustrate an example of etching process S5. FIG. 10 shows a portion of the X-Z cross section of the object to be processed 10.

In the example of etching process S5, as shown in FIG. 10, the precursor film 107 of the lower region below the oxidized portion 171 and region R2 are removed by etching while the silylated portion 108 remains, and the recess H is etched. As a result, the exposed portion of the inner wall surface HA and the inner bottom surface HB are etched. As a result, the first layers 103 and second layers 104 located below the inner bottom surface HB are further etched and the depth of the recess H is increased.

The etching is, for example, RIE. Etching is performed by supplying a fourth gas from the gas supply source 54, generating plasma from the fourth gas by supplying high-frequency power from the power supply unit 4, and removing the lower region below the oxidized portion 171 and the region R2 by sputtering with the plasma, as well as etching the recess H. The supply of the fourth gas and high-frequency power is stopped after the etching.

The fourth gas has, for example, carbon atoms, hydrogen atoms, and fluorine atoms. The fourth gas may be, for example, a fluoride gas represented by the composition formula CₓH_{y}F_{z} (C represents carbon, H represents hydrogen, F represents fluorine, x represents an integer of 1 or more, y represents an integer of 0 or more, and z represents an integer of 2 or more).

The silylated portion 108 functions a as protective film to inhibit etching by the plasma generated from the fourth gas. This allows etching of the region R1 covered by the silylated portion 108 to be suppressed. In addition, the lower region below the oxidized portion 171 and the region R2 where the silylated portion 108 is not formed can be removed and the recess H can be etched deeply with accuracy.

Etching may form a film 109 on the silylated portion 108. The film 109 includes carbon atoms, nitrogen atoms, and fluorine atoms. The film 109 functions as a protective film to inhibit etching by the plasma generated from the fourth gas. The film 109 may, for example, contain 40% to 60% carbon (C) atoms, 10% to 20% nitrogen (N) atoms, and 20% to 30% fluorine (F) atoms, for a total of 100% of the atoms.

The silylated portion 108 and the film 109 formed by the etching process S5 are removed together with the oxidized portion 171 using a method such as ashing with oxygen plasma under a temperature of 250° C. or higher, for example, before the memory layer formation process S6.

In the example of the etching method and the example of the semiconductor device manufacturing method of the embodiments, these processes are repeated until the aspect ratio of the recess H becomes greater than a desired value.

In the etching process using etching gas containing fluorinated hydrocarbon compounds, the recess tapers easily from the top to the bottom of the recess. This is because the plasma generated from the etching gas is less likely to reach the lower (bottom) part of the inner wall surface of the recess, and etching tends to increase at the upper part of the inner wall surface of the recess. As a result, a difference in the cross-section in the XY plane tend to occur from the top to the bottom of the recess H in the Z direction.

In contrast, in the example of the etching method and the example of the manufacturing method of the semiconductor device of the embodiments, an oxidized portion having silicon atoms is formed on a portion of the inner wall surface from the top to the bottom of the recess before the silylation process. And then, the oxidized portion is silylated to form a silylated portion, thereby suppressing the etching process at the top of the inner wall surface of the recess. The etching process can be suppressed in the upper region of the inner wall surface of the recess, while the lower region of the inner wall surface and the inner bottom surface can be etched. Therefore, even when forming a recess H with a high aspect ratio, the processing accuracy of the recess H can be improved. As a result, it is possible to control the cross-section in the XY plane of the recess H uniformly from the top to the bottom of the recess H in the Z direction, which allows for etching deeply with accuracy.

### Memory Layer Formation Process S6

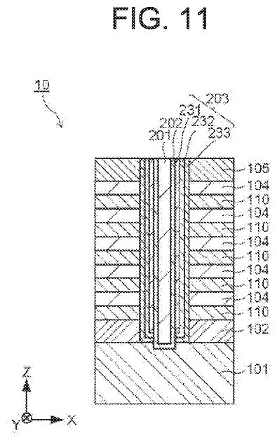

FIG. 11 is a cross-sectional schematic diagram to illustrate an example of the memory layer formation process S6. FIG. 11 shows a portion of the X-Z cross section of the object to be processed 10.

In the memory layer formation process S6, a memory film 203 including a block insulating film 233, a charge storage layer 232, and a tunnel insulating film 231, a semiconductor channel layer 202, and a core insulating film 201 are formed in the recess H in this order. The core insulating film 201, semiconductor channel layer 202, and memory film 203 function as memory layers that constitute a memory cell.

As the core insulating film 201, for example, a silicon oxide layer can be used. As the semiconductor channel layer 202, a polysilicon layer can be used, for example. As the tunnel insulating film 231, a stacked film having, for example, a silicon oxide layer and a silicon oxynitride film can be used. As the charge storage layer 232, for example, a silicon nitride layer can be used. As the block insulating film 233, for example, a silicon oxide layer can be used.

After forming the memory film 203, the first layers 103 are removed, cavities are formed between second layers 104. Then, conductive layers 110 are formed by stacking multiple conductive films in the cavities. The conductive layers 110 function as gate electrodes (word lines), for example. Furthermore, contact plugs, wirings, interlayer insulating films, etc. are formed. This allows the semiconductor device to be manufactured.

Although a memory hole in which a memory layer is formed is illustrated as an example of a recess H in this embodiment, the application of this embodiment is not limited to memory holes. For example, this embodiment can be applied to various types of recesses, such as a groove (ST) for replacing sacrificial layers (first layers 103) with conductive layers 110 or a hole for forming a contact plug connected to the conductive layers 110.

While certain embodiments have been described, these embodiments have been presented by way of example only, and are not intended to limit the scope of the disclosure. Indeed, the novel embodiments described herein may be implemented in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An etching method for an object to be processed having a recess, the recess having an inner wall surface, the etching method comprising;
forming a first film on the inner wall surface of the recess by supplying a precursor including silicon to the recess;
oxidizing an upper region of the first film on the inner wall surface by an oxidation process, thereby forming an oxidized portion in the upper region;
silylating the oxidized portion by supplying a silylating agent to the recess; and
etching the recess after supplying the silylating agent to increase the depth of the recess.

2. The etching method according to claim 1, wherein the precursor is at least one of dichlorosilane (DCS), tetrachlorosilane (SiCl₄), bis(t-butylamino)silane (BTBAS), and bis(diethylamino)silane (BDEAS).

3. The etching method according to claim 1, wherein the silylating agent includes silicon, hydrogen and carbon.

4. The etching method according to claim 1, wherein the oxidation process does not oxidize a lower region of the first film on the inner wall surface, the lower region being below the upper region.

5. The etching method according to claim 1, wherein the oxidized portion is formed by the oxidation process using oxygen plasma.

6. The etching method according to claim 1, wherein the etching of the recess is performed using a fluoride gas represented by the composition formula CₓH_{y}F_{z} (C represents carbon, H represents hydrogen, F represents fluorine, x represents an integer of 1 or more, y represents an integer of 0 or more, and z represents an integer of 2 or more).

7. The etching method according to claim 1, further comprising:
forming a second film including carbon, fluorine, and nitrogen on the silylated oxidized portion.

8. The etching method according to claim 1, wherein silylating the oxidized portion is performed after alternately repeating the formation of the first film and the oxidation.

9. The etching method according to claim 4, wherein the first film of the lower region is removed by the etching.

10. The etching method according to claim 1, wherein the first film formation, the oxidation, the silylation, and the etching are performed continuously using a same apparatus without exposing the object to be processed to air outside the apparatus.

11. A manufacturing method of a semiconductor memory device from an object that includes a semiconductor substrate having a recess, the recess having an inner wall surface, the manufacturing method comprising:
supplying a precursor including silicon to the recess to form a first film on the inner wall surface of the recess;
oxidizing an upper region of the first film on the inner wall surface by an oxidation process;
supplying a silylating agent to the recess; and
etching the recess to increase the depth of the recess.

12. The manufacturing method according to claim 11, wherein the precursor is at least one of dichlorosilane (DCS), tetrachlorosilane (SiCl₄), bis(t-butylamino)silane (BTBAS), and bis(diethylamino)silane (BDEAS).

13. The manufacturing method according to claim 11, wherein the silylating agent includes silicon, hydrogen and carbon.

14. The manufacturing method according to claim 11, wherein the oxidation process does not oxidize a lower region of the first film on the inner wall surface, the lower region being below the upper region.

15. The manufacturing method according to claim 11, wherein the oxidation process is performed using oxygen plasma.

16. The manufacturing method according to claim 11, wherein the recess is formed in a plurality of first layers and a plurality of second layers that are alternately stacked above the substrate, and
the etching of the recess is performed using a fluoride gas represented by the composition formula CₓH_{y}F_{z} (C represents carbon, H represents hydrogen, F represents fluorine, x represents an integer of 1 or more, y represents an integer of 0 or more, and z represents an integer of 2 or more).

17. The manufacturing method according to claim 11, wherein a silylated oxidized portion is formed by supplying the silylating agent, and the method further comprising:
forming a second film including carbon, fluorine, and nitrogen on the silylated oxidized portion.

18. The manufacturing method according to claim 11, wherein supplying the silylating agent is performed after alternately repeating the formation of the first film and the oxidation.

19. The manufacturing method according to claim 14, wherein the first film of the lower region is removed by the etching.

20. The manufacturing method according to claim 11, wherein the first film formation, the oxidation, the silylation, and the etching are performed continuously using a same apparatus without exposing the object to be processed to air outside the apparatus.
